(19) United States
(12) Patent Application Publication
(10) Pub. No.: US 2026/0243825 A1
(43) Pub. Date: Aug. 20, 2026

(54) Portable device and method for performing multiple tests on an electronic circuit

(71) Applicant: 9469-4031 QUEBEC INC., Sherbrooke (CA)

(72) Inventor: Patrick Allen, Sherbrooke, QC (CA)

(21) Appl. No.: 19/164,180

(22) PCT Filed: Mar. 11, 2024
(86) PCT No.: PCT/CA2024/050297

§ 371 Date: Sep. 10, 2025

Related U.S. Application Data
(60) Provisional application No. 63/489,555, filed on Mar. 10, 2023.

(51) Int. Cl. G01R 31/319; G01R 1/04; G01R 1/067; G01R 31/317

(52) U.S. Cl. CPC G01R 31/31914; G01R 1/04; G01R 1/06788; G01R 31/31713; G01R 31/31912

(57) ABSTRACT

A portable device for performing multiple tests on an electronic circuit is provided. The device generally allows the diagnosis of failing circuitry components and/or in the context of prevention against potential failures. The device comprises an LCD screen to display sinusoidal curves and draw conclusions based on the curves. This single multi-purpose apparatus allows the user to make several tests among which, an I/V curve tracer, an oscilloscope, an ohmmeter, a capacitor tester, an inductor ringer, a diode check, a Zener check, and a voltmeter. The device is compact, easy to transport and to carry, and cost and time effective as it does not require the use of a transformer to operate and only requires the user to chose which test to perform.

WO

### CROSS-REFERENCE TO RELATED APPLICATIONS

The present patent application claims the benefits of priority of U.S. Provisional Patent Application No. 63/489,555, entitled “PORTABLE DEVICE AND METHOD FOR PERFORMING MULTIPLE TESTS ON AN ELECTRONIC CIRCUIT” and filed at the United States Patent and Trademark Office on Mar. 10, 2024, the content of which is incorporated herein by reference.

### FIELD OF THE INVENTION

The present invention is generally related to devices and methods for performing multiple tests on an electronic circuit. More particularly, the present invention relates to electronic test instruments and methods used for the diagnostic of an electronic component of a circuit, and, in some embodiments, to test electronic circuits of industrial machines.

### BACKGROUND OF THE INVENTION

Passive circuit board components may be tested by applying a stimulus signal to a device and measuring the reaction of the voltage and current of the components to these stimuli. One major lack of the testing industry is the lack of testing instruments that can perform different types of tests using a single machine. When they do, the testing instruments become larger and cumbersome to use and to transport.

One such test instrument is the one disclosed by Fluke Corporation (U.S. Pat. No. 5,508,607 A). The test instrument of Fluke Corporation provide a portable test instrument like a digital multimeter having a graphical display. The test instrument allows measuring voltage or impedance measurements and generates a curve for the results. Indeed, such test instrument allows testing of components at high voltage and capacitance, and uses a transformer to plot the results. However, the test instrument disclosed by Fluke Corporation may not be used to capture a plurality of measurements and to provide results for a plurality of tests using such measurements.

Another apparatus that offers a multitude of tests is the apparatus disclosed in the U.S. Pat. No. 4,386,317A by Huntron Instruments Inc., which allows to test semi-conductor junctions. However, this apparatus also uses a transformer to offer several tests into a single invention. For that reason, it is quite voluminous and heavy and lacks portability. As such, the instrument disclosed by Huntron lacks in portability and is typically not used by a technician on-the-go. Furthermore, the said instrument is limited to provide curve tracer I/V.

Moreover, existing testing devices are permanent and voluminous. As such, the existing testing devices may no be easily carried to the machine to be tested. Most of the times, the machines to be tested must be disconnected or shipped to a location where the testing equipment is present. Such procedure may be cumbersome and extremely costly for the owner of the machine to be tested.

There is thus a need for a portable system for performing multiple tests on an electronic circuit or on some components of an electronic circuit.

### SUMMARY OF THE INVENTION

The shortcomings of the prior art are generally mitigated by many advantages such as portability, ease of use, low volume and weight, integration of several tools into one single tool, efficient rechargeability and the use of a small-sized long-life battery. The invention helps minimise the number of manipulations during troubleshooting and integrates many important tools for troubleshooting defective components that are never seen together in a single tool.

The invention is preferably used as a troubleshooting device, although it may comprise measurement tools. One of the invention's goals is to help technicians perform quick and accurate diagnosis of electronic failures and/or a low-cost diagnosis of parts in prevention of a failure.

Another aspect of the invention is to provide a portable and handheld testing unit to test an electronic circuit on site of a machine. The handheld device is adapted to perform high-level diagnosis of the machines to be tested and to prevent unnecessary expenses related to shipping and carrying the machine, or in turning off the machine and stopping production. In some embodiments, the testing device may comprise a case having side with dimension of about three to five inches.

In one aspect of the invention, a portable device for performing multiple tests on an electronic circuit, such as but not limited to a defective electronic circuit, is provided. The portable device comprises a portable power source, a housing comprising a display screen, a plurality of testing modules powered by the portable power source within the housing, the testing modules comprising a measured current as a function of voltage (I/V) component curve tracer, a capacitor tester, an ohmmeter, a voltmeter, a Zener diode tester, a diode tester, and an oscilloscope. The device further comprising a human-device interface configured to select a testing mode and an electronic module powered by the portable power source and connected to each of the testing modules, the electronic module comprising a testing module control module configured to activate/deactivate a plurality of the testing modules based on the selected testing mode.

The housing may have dimensions to be held in a hand of a user. The length and width of the housing may range between three and five inches in width and height.

The human-device interface may comprise buttons, each button selecting the testing mode. The portable device may comprise input/output (I/O) ports for connecting external sensors or devices. The display screen may be a capacitive screen, the human-device interface being configured to select testing modes by touching the touch screen.

The portable device may further comprise a retractable support member for holding the device in an upright position.

The electronic module may comprise a processor, a power supply, a signal conditioner, and step-up regulators. The processor may be configured to dynamically activate or deactivate one or more testing modules when not required for the selected testing mode to reduce power consumption. The processor may be configured to compute test results and graphs based on measurements of the testing module based on the selected testing mode.

The portable device may further comprise a Universal Serial Bus (USB) port, the USB port configured to establish data transfer port with external devices. The portable device of claim 1 may comprise conductive probes, the electronic module being configured to generate a stimulus signal and to provide the stimulus signal to the electronic circuit being tested.

The portable device may comprise an electrical response signal comparator configured to compare a response of the stimulus signal with expected responses based on the selected testing mode.

In another aspect of the invention, a method for performing multiple tests on an electronic circuit using a portable device to minimize human manipulation during testing is provided. The method comprises selecting a testing mode, the portable device generating a stimulus signal applying the stimulus signal to the tested electronic circuit, detecting an electrical response signal on the electronic circuit using one or more testing components based on the selected testing mode, comparing the detected electrical response signal with expected responses based on the selected testing mode and dynamically switching between testing modes to analyze different aspects of the electronic circuit.

The generation of the stimulus signal may comprise generating a digital sine wave. The application of the stimulus signal may include transmitting the signal through conductive probes. The comparing of the detected response may comprise analyzing I/V traces and live values. The step of dynamically switching between testing modes may comprise activating/deactivating testing modules based on the selected mode.

The method may further comprise computing test results and graphs based on measurement of the testing modules and graphically displaying the test results and the graphs to the user. The method may comprise activating only the required testing modules based on the selected testing mode to reduce power consumption of the portable device.

Other and further aspects and advantages of the present invention will be obvious upon an understanding of the illustrative embodiments about to be described or will be indicated in the appended claims, and various advantages not referred to herein will occur to one skilled in the art upon employment of the invention in practice.

### BRIEF DESCRIPTION OF THE DRAWINGS

The above and other aspects, features and advantages of the invention will become more readily apparent from the following description, reference being made to the accompanying drawings in which:

FIG. 1 is a front perspective view of an embodiment of a device for performing multiple tests on an electronic circuit in accordance with the principles of the present invention.

FIG. 2 is a top perspective view of embodiments of a printed circuit board (PCT), a display screen and power source of a device for performing multiple tests on an electronic circuit in accordance with the principles of the present invention.

FIG. 3 is a side perspective view of an embodiment of an enclosure of a device for performing multiple tests on an electronic circuit in accordance with the principles of the present invention showing a rear flip tab acting as the support for the.

FIG. 4 is a block diagram of components of an embodiment of a device for performing multiple tests on an electronic circuit in accordance with the principles of the present invention.

FIG. 5 is a front view of another embodiment of a device for performing multiple tests on an electronic circuit in accordance with the principles of the present invention.

FIG. 6 is a left view of the device of FIG. 5 showing embodiments of input ports.

FIG. 7 is a right view of the device of FIG. 5 showing an embodiment of a USB port.

FIG. 8 is a top view of the device of FIG. 5.

FIG. 9 is a front perspective view of the device of FIG. 5.

FIG. 10 is a front perspective view of the device of FIG. 5, shown with a rear support member in an open configuration.

FIG. 11 is a rear perspective view of the device as embodied in FIG. 10.

### DETAILED DESCRIPTION OF THE INVENTION

A novel portable device and method for performing multiple tests on an electronic circuit will be described hereinafter. Although the invention is described in terms of specific illustrative embodiments, it is to be understood that the embodiments described herein are by way of example only and that the scope of the invention is not intended to be limited thereby.

The present invention generally provides an electronic device 10 integrating a plurality of operational testing devices. The testing devices are integrated and combined in a compact, handheld and/or portable device. The electronic device 10 generally aims at simplifying diagnosis of electronic boards or components of the same. The electronic device 10 is configured to provide a plurality of test modes, such as but not limited to a measured current (I) as a function of voltage (V) component curve tracer 402, also referred as an I/V curve tracer. The tracer may be operable in multi mode, frequency and amplitude, multi channel (A-B mode), a capacitor tester 404 (i.e., ESR and value in uf), such as in short mode. The electronic device 10 may further comprise an ohmmeter 414, such ohmmeter 414 being operable in multi range and/or auto mode, voltmeter 416, such as the voltmeter 416 being operable in multi range and/or auto mode, Zener diode tester 412, standard diode tester 410, and basic oscilloscope 406.

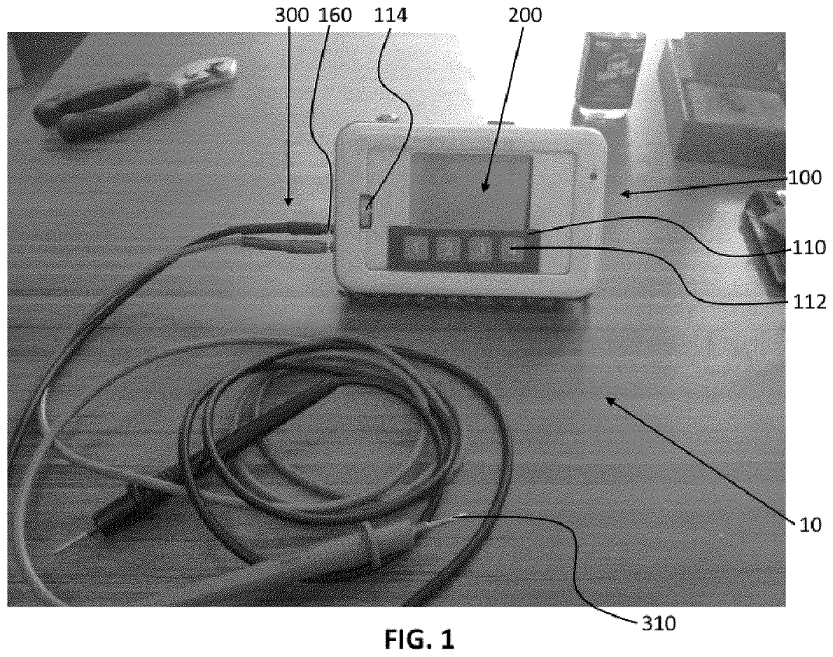

Referring to FIG. 1, an embodiment of a portable device 10 for performing multiple tests on an electronic circuit is illustrated. The device 10 typically comprises a housing or case 100, also referred as an enclosure, a display 200 and input/output ports 300.

The device 10 may comprise a human interface 110 allowing a user to interact with the device 10. The human interface 110 may be comprise one or more buttons 112, such as pressure button or tactile buttons. The human interface 110 may be configured to allow switching between modes. In some embodiments, the device 10 comprises four buttons 112, each button 112 being associated with a different mode of operation. Understandably, any number of buttons 112 may be present on the device.

The human interface 110, or buttons 112, may be dynamic or may have changeable functions. As such, each button 112 may perform a specific function associated with the mode of testing that is selected. As an example, in embodiments comprising four buttons 112, each of the buttons 112 may be associated to specific function of curve tracing when the curve tracer mode is selected. When another operating mode is selected, the buttons 112 are mapped to new functions associated with the newly selected operating mode.

The human interface 110 may further comprise knobs 114. In some embodiments, the knobs 114 may be configured to vary the power level, intensity level or any other settings of a selected mode of operation of the device 10. In some further embodiments, the knobs 114 may be configured to select an operating mode of the device 10.

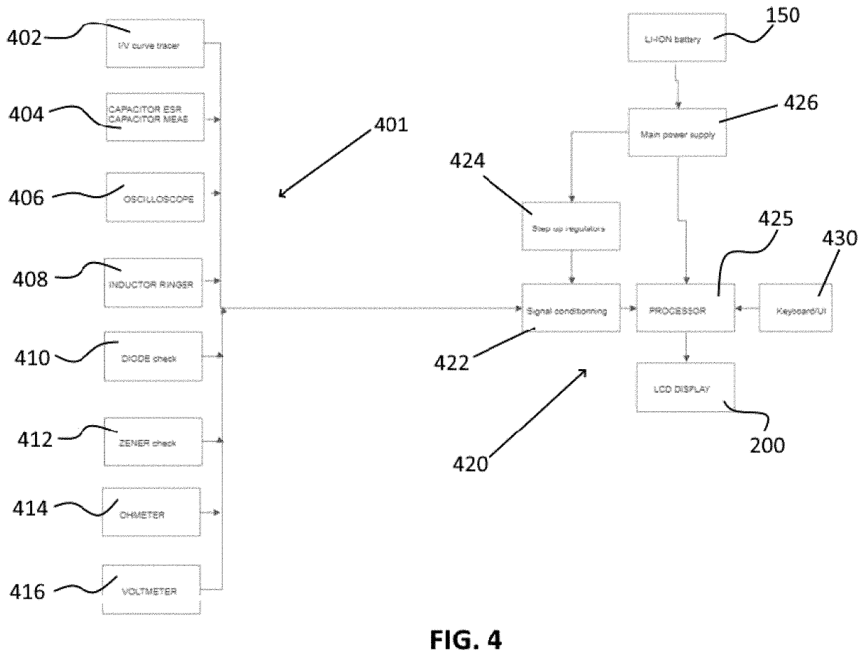

In yet other embodiments, the operating mode of the device 10 may be selected using a touch screen, with one or more buttons or using any other known human interface means adapted to select an operating mode amongst a plurality of available operating modes. As discussed above, when an operating mode is selected, the device 10 activates the required modules 401 (see FIG. 4) and deactivates the non required modules 401. The device 10 further presents data on the display that is relevant to the selected mode of testing and maps the buttons 112 with functions, actions, or modes of operations specific to the selected mode of testing.

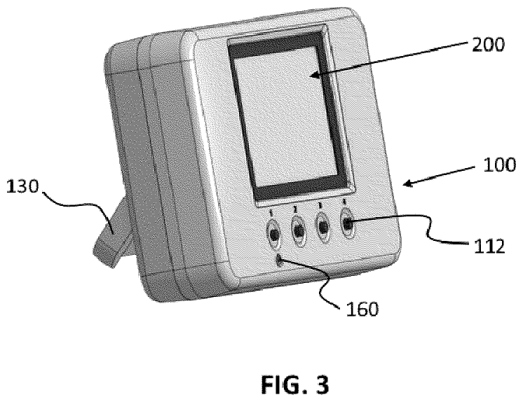

Referring now to FIG. 3, the device 10 may further comprise a retractable support member 130 for holding the device 10 in a substantially upright position. In some embodiments, the support member 130 is flip tab or flap pivotally attached on the rear side of the enclosure 100 of the device 10.

The housing 100 is shaped to be handheld. As such, the width and height of the housing 100 may range between three and five inches while depth may be around one to two inches. Understandably, any other dimensions allowing the device 10 to be handheld and portable are within the scope of the present invention.

The device 10 comprises input-output ports 300 adapted to connected to an external sensor or to communicate the results to another device. The external sensor may be a conductive probe 310. The conductive probe 310 typically comprises a sensor adapted to collect a signal from the tested component.

The input-output ports 300 may comprise any communication port, such as a Universal Serial Bus (USB) port. The USB port may be used to provide charging to the battery of the device 10 or may act as a power source for the device 10. In some embodiments, the USB port may be connected to an external computerized device, such as a computer, a smart phone, a tablet, or any other known computerized device, to provide a bidirectional communication link with the external computerized device. As an example, the bidirectional port may be used to retrieve a software or bios update to be applied to the device. In yet other embodiments, the bidirectional port may be connected to a to a management system to transmit diagnostic data. The bidirectional port may further be connected to a device having a display means configured to display diagnostic information or any other data transmitted by the device 10. Understandably, the device 10 may further comprise a network communication port, such as a wireless antenna, to transmit the information to an external device connected to the remote or local network in communication with the network communication port.

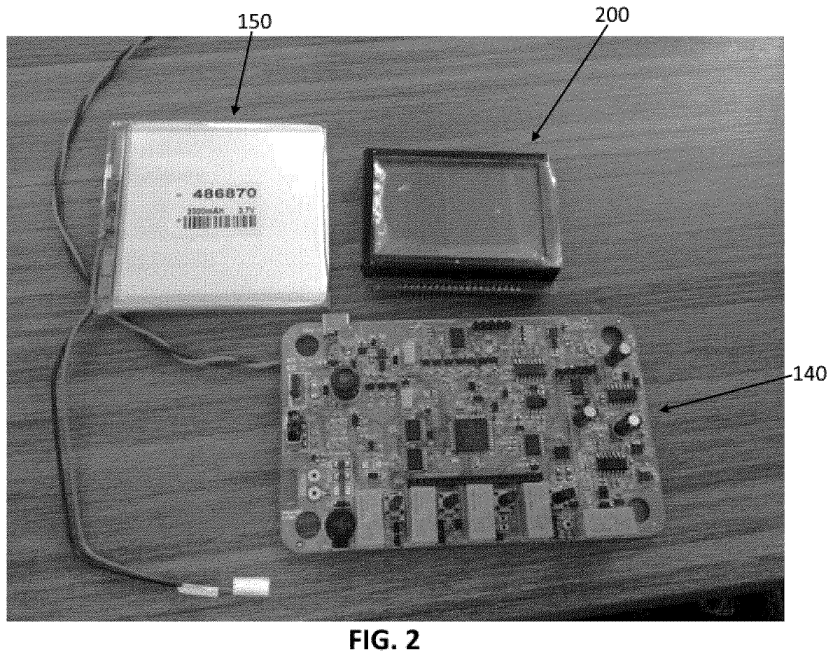

Referring now to FIG. 2, embodiments of inner components of the device 10 are illustrated. The device 10 comprises a PCB 140, a portable power source 150, such as a li-ion battery and the display screen 200, such as but not limited to an LCD.

The PCB 140 generally comprises the electronic components to perform a plurality of tests. In such an embodiment, the electronic components allow performing seven tests on the electronic circuit to be tested. The PCB 140 comprises a processor adapted to generate a digital sine wave simulating a sine wave. The PCB further comprises step-up regulators amplifying the voltage receive from the portable power source (i.e., 3.6v).

The PCB 140 further comprises a plurality of conditioning circuits adapting the amplified signal to be received by the processor. The processor is configured to use the conditioned signal to output the simulated digital sine wave.

The probes 310 are in signal communication with the PCB 140. The probes 310 transmit the signal present at a contact point of the circuit. The read signal is communicated to the processor. Based on the selected mode of operation, the processor calculated the test results. In some embodiments, the test results are displayed on the LCD display. In some embodiments, the processor is a 16-bit microchip processor to reduce the power consumption of the battery. In some embodiments, the display screen is an LCD screen. The LCD screen 200 may display video of the signature of the device to be tested in vivid and active images. In some embodiments, the display is a 64×128 dot display.

In some embodiments, the display screen 200 may display I/V traces and/or live values. The display screen 200 may further be used as the user interface (i.e., a touch screen) and thus may allow switching between modes of use.

Referring now to FIG. 3, the LCD screen 200 may be attached in a recess of the enclosure 100. In such embodiment, the enclosure 100 comprises four buttons 112 and an input port 160 connectable to the probes 310.

Referring now to FIG. 4, a block diagram of components of the device 10 is illustrated. The device 10 comprises a plurality of modules 401 each adapted for testing different aspects of an electronic circuit, such as an I/V curve tracer 402, a capacitor tester 404, an oscilloscope 406, an inductor ringer 408, a diode check 410, a Zener check 412, an ohmmeter 414, and a voltmeter 416.

Each of the modules 401 is configured to receive an electrical input from a component of the electric circuit being tested. As illustrated at FIG. 4, the device 10 comprises an electronic circuit 420 shared with all the modules 401. The shared electronic circuit 410 typically comprises a processor 425 in signal communication with the modules 401. The shared electronic circuit 420 may further comprise a power supply 426 powered by the portable power source 150. In the illustrated circuit, the processor 425 is in data communication with the display 200 and input devices 430, such as but not limited to keyboard and user interface (UI). The shared circuit 420 may further comprise a signal conditioner 422 and one or more step-up regulators 424 in data communication with the processor 425.

The processor 425 is configured to activate the one or more module 401 required to perform the function selected via the UI 430. The processor 425 thus powers the required modules 401 and deactivates the unrequired modules 401. As such, the required electrical power is considerably reduced to limit power consumption of the device 10. The shared circuit 425 may comprise a switcher module to activate/deactivate the modules 401 or the processor 424 may comprise a map of the modules 401 activated for each selectable function. The shared circuit 420 or processor 424 may further be configured to adapt the display 200 or to change mapping of the buttons 112 according to the selected function. As such, the display 200 displays different information or graphs based on the selected function.

Each module is connected to the signal conditioner 422. The conditioner 422 is configured to change the signal according to the activated modules 401. The conditioned signals are then communicated to the processor 425 which may be interacted with by the buttons 112 and a human interface 110. The processed signals are then displayed on the LCD screen 200. The power from the battery, such as a LI-ion battery, is the main power supply, and is sent to directly power the processor or the signal conditioner 422 through step up regulators 424.

As discussed above, as the shared circuit 420 is configured to enable/disable the different modules 401, the shared circuit generally acts as a power regulator for the device 10. Using only a subset or one of the modules 401 allows reducing power consumption and thus allows longer uses of the portable device 10 when perform tests on remote machines or in small areas of machines. The reduced electrical power consumption generally allows the use of a portable power source 150, such as a battery. One skilled in the art shall understand that the shared electronic circuit 420 greatly reduces the volume of the device 10 as there is no need for electronic circuits for each of the modules 401.

The device 10 generally reduces the cost related to testing components. The reduced dimensions generally aim at easing manipulations required during performing debugging or problem finding on a faulty electronic device, electronic board or at the component level itself. As the different tests are performed in a single unit, the manipulation of the probes 310 is strictly minimised, only requiring the user to switch between modes for the desired test.

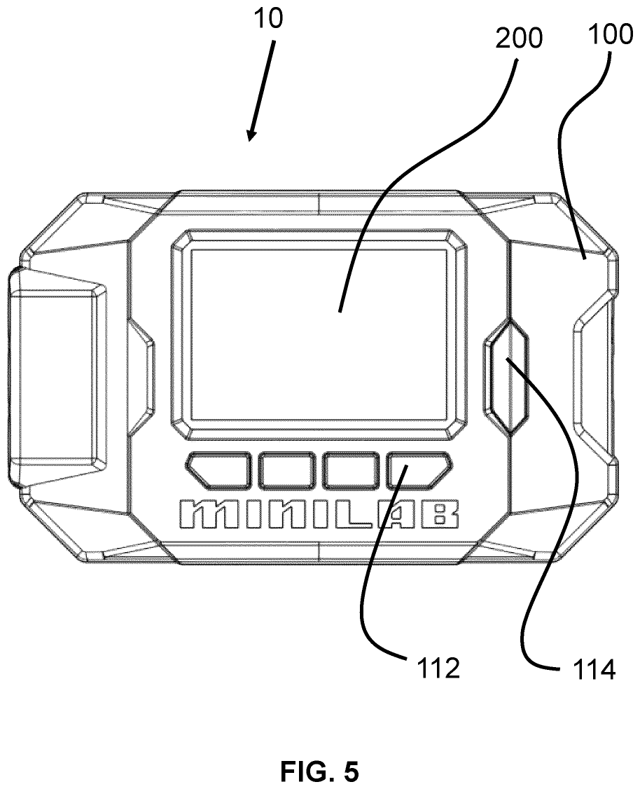

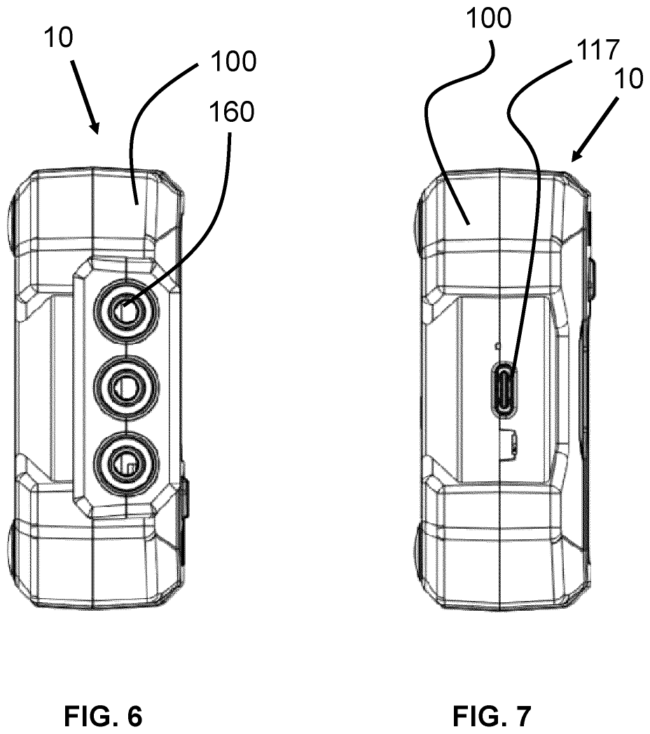

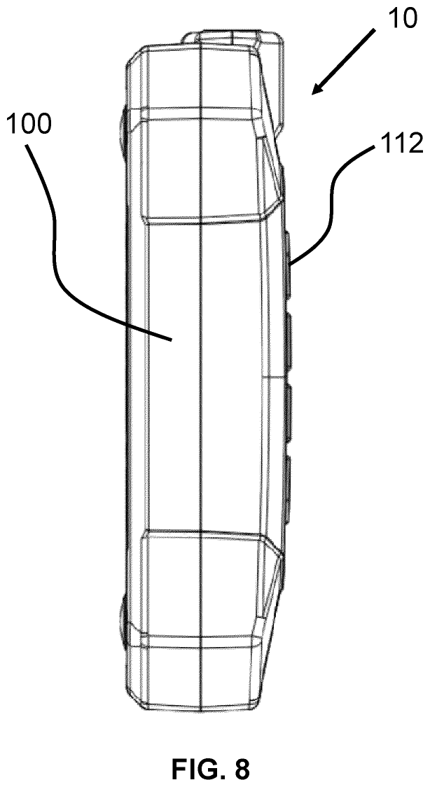

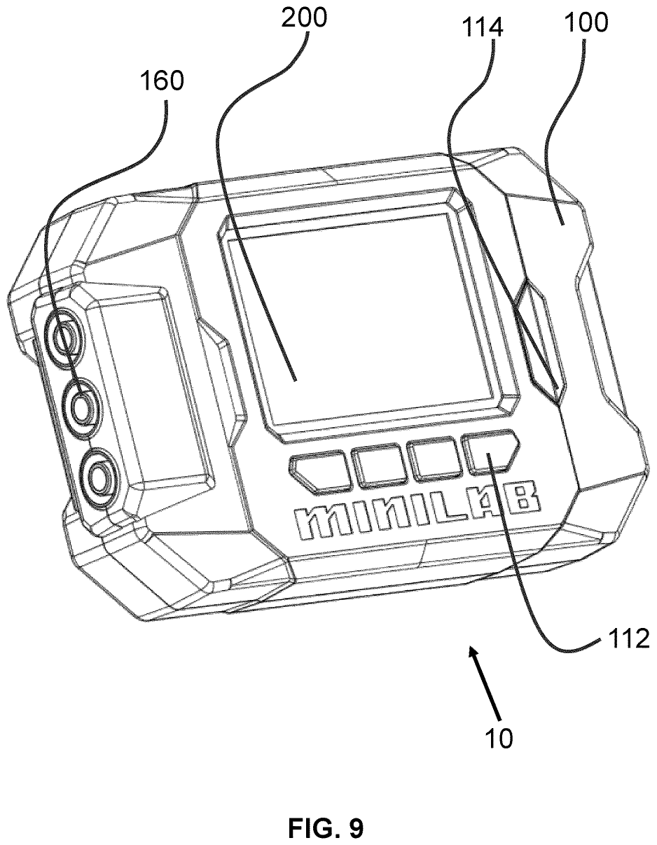

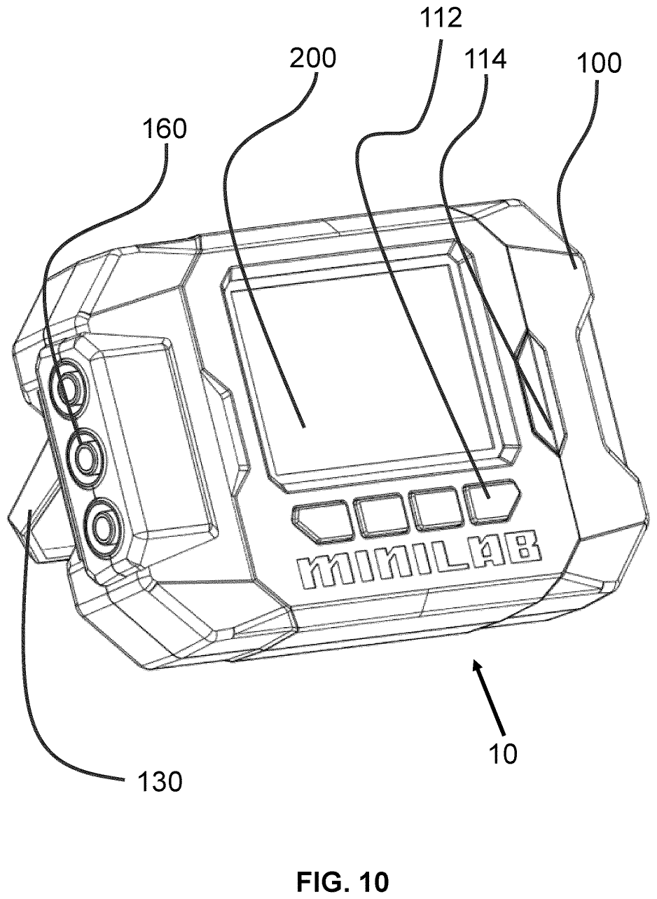

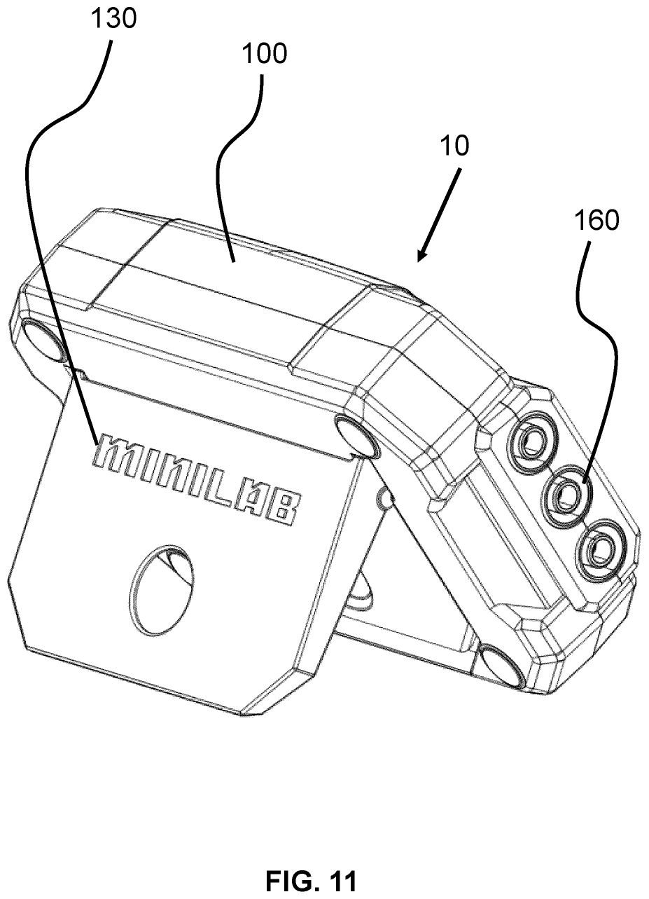

Referring now to FIGS. 5-11, another embodiment of the device 10 is illustrated. In such embodiment, the device comprises a housing 100 having a screen 200, buttons 112, a knob 114, input ports 160, and a USB port 117. The device 10 may further comprise a rear support member 130 adapted to hold the device 10 in an upright position. Referring to FIG. 11, in the illustrated embodiment, the rear support member 130 is pivotally attached to the housing 100, allowing an open configuration for the support member 130 to be in contact with an external surface to hold the device 10.

In the illustrated embodiment, the housing 100 has a rugged configuration adapted to be used in any environment. As such, the housing 100 may comprise softer or resilient material such as rubber to absorb impacts. In yet other embodiments, the housing may be made of hard plastic.

The device 10 may be used to test electronic circuits of industrial machines, commercial installations, domestic environments, automotive circuitry, railroad equipment and/or any other environments requiring to test and repair defective or functional electronic circuits.

A method for performing multiple tests on an electronic circuit is provided. The method for testing the probes generally comprises generating a stimulus signal and communicating the generated signal to an electronic circuit or electronic component to be tested. The method further comprises detecting an electrical signal from the tested component as a response to the provided stimulus. The method further comprising the comparing the detected response to the stimulus to the expected response from a normally functioning electronic circuit or component. The method further comprises dynamically switching between different testing devices to compare the detected response to other expected responses from a normally functioning electronic circuit or component.

While illustrative and presently preferred embodiments of the invention have been described in detail hereinabove, it is to be understood that the inventive concepts may be otherwise variously embodied and employed and that the appended claims are intended to be construed to include such variations except insofar as limited by the prior art.

1) A portable device for performing multiple tests on a electronic circuit, the portable device comprising:
a portable power source;
a housing comprising
a display screen;
a plurality of testing modules powered by the portable power source within the housing, the testing modules comprising a measured current (I) as a function of voltage (I/V) component curve tracer, a capacitor tester, an ohmmeter, a voltmeter, a Zener diode tester, a diode tester, and an oscilloscope;
a human-device interface configured to select a testing mode to be applied on the electronic circuit; and
an electronic module powered by the portable power source and connected to each of the testing modules, the electronic module comprising a testing module control module configured to concurrently activate/deactivate a plurality of the testing modules based on the selected testing mode.

2) The portable device of claim 1, the housing having dimensions to be held in a hand of a user.

3) The portable device of claim 2, the length and width of the housing ranging between three and five inches in width and height.

4) The portable device of claim 1, the human-device interface comprises buttons, each button selecting the testing mode.

5) The portable device of claim 1 further comprising input/output (I/O) ports for connecting external sensors or devices.

6) The portable device of claim 1, the display screen being a capacitive screen, the human-device interface being configured to select testing modes by touching the touch screen.

7) The portable device of claim 1 further comprising a retractable support member for holding the device in an upright position.

8) The portable device of claim 1, the electronic module comprising a processor, a power supply, a signal conditioner, and step-up regulators.

9) The portable device of claim 8, the processor being configured dynamically activate or deactivate one or more testing modules when not required for the selected testing mode to reduce power consumption.

10) The portable device of claim 9, the processor being configured to compute test results and graphs based on measurements of the testing module based on the selected testing mode.

11) The portable device of claim 1 further comprising a Universal Serial Bus (USB) port, the USB port configured to establish data transfer port with external devices.

12) The portable device of claim 1 comprising conductive probes, the electronic module being configured to generate a stimulus signal and to provide the stimulus signal to the electronic circuit being tested.

13) The portable device of claim 12 further comprising an electrical response signal comparator configured to compare a response of the stimulus signal with expected responses based on the selected testing mode.

14) A method for performing multiple tests on a electronic circuit using a portable device to minimize human manipulation during testing, comprising:
selecting a testing mode;
the portable device generating a stimulus signal based on the selected testing mode and applying the stimulus signal to the tested electronic circuit;
detecting an electrical response signal on the electronic circuit using one or more testing components based on the selected testing mode;
comparing the detected electrical response signal with expected responses based on the selected testing mode; and
dynamically switching between testing modes to analyze different aspects of the electronic circuit.

15) The method of claim 14, wherein the generation of the stimulus signal includes generating a digital sine wave.

16) The method of claim 14, wherein the application of the stimulus signal includes transmitting the signal through conductive probes.

17) The method of claim 14, wherein the comparing of the detected response includes analyzing I/V traces and live values.

18) The method of claim 14, wherein the step of dynamically switching between testing modes includes activating/deactivating testing modules based on the selected mode.

19) The method of claim 14, further comprising computing test results and graphs based on measurement of the testing modules and graphically displaying the test results and the graphs to the user.

20) The method of claim 14, further comprising activating only the required testing modules based on the selected testing mode to reduce power consumption of the portable device.
